(19) United States
(12) Patent Application Publication
(10) Pub. No.: US 2025/0292837 A1
(43) Pub. Date: Sep. 18, 2025

(54) LATERAL SUB-BLOCK MODE IN A MEMORY DEVICE

(71) Applicant: Western Digital Technologies, Inc., San Jose, CA (US)

(72) Inventors: Peng Zhang, San Jose, CA (US); Wei Cao, Fremont, CA (US)

(21) Appl. No.: 18/603,582

(22) Filed: Mar. 13, 2024

(51) Int. Cl. G11C 16/10; G11C 16/08; G11C 16/28

(52) U.S. Cl. CPC G11C 16/102; G11C 16/08; G11C 16/28

(57) ABSTRACT

The memory device includes a memory block with an array of memory cells that are arranged in a plurality of word lines and that are divided into at least two laterally divided sub-blocks. Control circuitry programs the memory cells of one of the sub-blocks in a plurality of program loops. During at least one of the program loops, the control circuitry ramps down a selected word line being programmed from a reference voltage. After beginning to ramp down the selected word line from the reference voltage, the control circuitry sequentially ramps down a plurality of unselected word lines from pass voltages from nearest the selected word line to the opposite ends of the memory block. Then, the control circuitry ramps up a plurality of unselected word lines that are distant from the selected word line. Next, the control circuitry ramps up the selected word line to a programming voltage.

### BACKGROUND

### 1. Field

The subject disclosure is related generally to techniques for more efficiently operating a memory device in a lateral sub-block mode.

### 2. RELATED ART

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery.

NAND memory devices include a chip with a plurality of memory blocks, each of which includes an array of memory cells arranged in a plurality of word lines. Programming the memory cells of a word line to retain data typically occurs in a plurality of program loops, each of which includes the application of a programming pulse to a control gate of the word line and, optionally, a verify operation to sense the threshold voltages of the memory cells being programmed. Each program loop may also include a pre-charge operation prior to the programming pulse to pre-charge a plurality of channels containing memory cells to be programmed.

### SUMMARY

One aspect of the present disclosure is related to a method of performing a programming operation in a memory device. The method includes the step of preparing a memory block that includes an array of memory cells that are arranged in a plurality of word lines. With the memory block operating in a lateral sub-block mode, the method proceeds with the step of ramping down a selected word line being programmed from a reference voltage. After beginning to ramp down the selected word line from the reference voltage, the method continues with the step of sequentially ramping down a plurality of unselected word lines from pass voltages from nearest the selected word line to the opposite ends of the memory block. After the unselected word lines have been sequentially ramped down, the method proceeds with the step of ramping up a plurality of unselected word lines that are distant from the selected word line. After the unselected word lines that are distant from the selected word line have begun to ramp up, the method continues with the step of ramping up the selected word line to a programming voltage.

According to another aspect of the present disclosure, the step of sequentially ramping down the plurality of unselected word lines begins with only ramping down at least two word lines that are nearest the selected word line and then only ramping down at least two next closest word lines and continues until all of the unselected word lines in the memory block have begun to ramp down from the pass voltages.

According to yet another aspect of the present disclosure, the step of sequentially ramping down the plurality of unselected word lines includes a first stage and a second stage. During the first stage, a first number of unselected word lines simultaneously begin to ramp down. During the second stage, a second number of unselected word lines simultaneously begin to ramp down. The second number of unselected word lines is greater than the first number of unselected word lines.

According to still another aspect of the present disclosure, the first number of unselected word lines includes no more than four unselected word lines.

According to a further aspect of the present disclosure, the step of ramping down the selected word line from the reference voltage includes ramping the selected word line down to a negative voltage.

According to yet a further aspect of the present disclosure, the step of sequentially ramping down the plurality of unselected word lines from the pass voltages includes ramping the unselected word lines down to approximately zero Volts.

According to still a further aspect of the present disclosure, after the step of ramping up the plurality of unselected word lines that are distant from the selected word line and prior to the step of ramping up the selected word line to the programming voltage, the method further includes the step of ramping up the selected word line from the negative voltage to a positive voltage that is less than the programming voltage.

According to another aspect of the present disclosure, after the step of ramping up the selected word line to the programming voltage, the method further includes the step of ramping up a plurality of remaining unselected word lines to pass voltages.

Another aspect of the present disclosure is related to a memory device for performing a programming operation. The memory device includes a memory block that includes an array of memory cells that are arranged in a plurality of word lines. The array is divided into at least two laterally divided sub-blocks. The memory device also includes control circuitry that is configured to program the memory cells of one of the sub-blocks in a plurality of program loops. During at least one of the program loops, the control circuitry is configured to ramp down a selected word line being programmed from a reference voltage. After beginning to ramp down the selected word line from the reference voltage, the control circuitry sequentially ramps down a plurality of unselected word lines from pass voltages from nearest the selected word line to the opposite ends of the memory block. After the unselected word lines have been sequentially ramped down, the control circuitry ramps up a plurality of unselected word lines that are distant from the selected word line. After the unselected word lines that are distant from the selected word line have begun to ramp up, the control circuitry ramps up the selected word line to a programming voltage.

According to another aspect of the present disclosure, when sequentially ramping down the plurality of unselected word lines, the control circuitry is configured to initially only ramp down at least two word lines that are nearest the selected word line and then only ramp down at least two next closest word lines and continue to ramp down the unselected word lines until all of the unselected word lines in the memory block have begun to ramp down from the pass voltages.

According to yet another aspect of the present disclosure, the control circuitry is configured to sequentially ramp down the plurality of unselected word lines in a first stage and a second stage. During the first stage, the control circuitry simultaneously begins to ramp down a first number of unselected word lines. During the second stage, the control circuitry simultaneously begins to ramp down a second number of unselected word lines. The second number of unselected word lines is greater than the first number of unselected word lines.

According to still another aspect of the present disclosure, the first number of unselected word lines includes no more than four unselected word lines.

According to a further aspect of the present disclosure, the control circuitry is configured to ramp down the selected word line from the reference voltage to a negative voltage.

According to yet a further aspect of the present disclosure, the circuitry is configured to sequentially ramp down the plurality of unselected word lines from the pass voltages to approximately zero Volts.

According to still a further aspect of the present disclosure, after ramping up the plurality of unselected word lines that are distant from the selected word line and prior to ramping up the selected word line to the programming voltage, the control circuitry is further configured to ramp up the selected word line from the negative voltage to a positive voltage that is less than the programming voltage.

According to another aspect of the present disclosure, after ramping up the selected word line to the programming voltage, the control circuitry is further configured to ramp up a plurality of remaining unselected word lines to pass voltages.

Yet another aspect of the present disclosure is related to an apparatus for performing a programming operation in a memory device. The apparatus includes a memory block that includes an array of memory cells that are arranged in a plurality of word lines. The array is divided into at least two laterally divided sub-blocks. The apparatus also include programming means for programming the memory cells of one of the sub-blocks in a plurality of program loops. During at least one of the program loops, the programming means is configured to ramp down a selected word line being programmed from a reference voltage. After beginning to ramp down the selected word line from the reference voltage, the programming means is configured to sequentially ramp down a plurality of unselected word lines from pass voltages from nearest the selected word line to the opposite ends of the memory block. After the unselected word lines have been sequentially ramped down, the programming means is configured to ramp up a plurality of unselected word lines that are distant from the selected word line. After the unselected word lines that are distant from the selected word line have begun to ramp up, the programming means is configured to ramp up the selected word line to a programming voltage.

According to another aspect of the present disclosure, when sequentially ramping down the plurality of unselected word lines, the programming means is configured to initially only ramp down at least two word lines that are nearest the selected word line and then only ramp down at least two next closest word lines and continue to ramp down the unselected word lines until all of the unselected word lines in the memory block have begun to ramp down from the pass voltages.

According to yet another aspect of the present disclosure, the programming means is configured to sequentially ramp down the plurality of unselected word lines in a first stage and a second stage. During the first stage, the programming means simultaneously begins to ramp down a first number of unselected word lines. During the second stage, the programming means simultaneously begins to ramp down a second number of unselected word lines. The second number of unselected word lines is greater than the first number of unselected word lines.

According to still another aspect of the present disclosure, the first number of unselected word lines includes no more than four unselected word lines.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope. The disclosure is described and explained with added specificity and detail through the use of the accompanying drawings in which:

FIG. 1A is a block diagram of an example memory device;

FIG. 1B is a block diagram of an example control circuit;

FIG. 1C is a block diagram of example circuitry of the memory device of FIG. 1A;

FIG. 2 depicts blocks of memory cells in an example two-dimensional configuration of the memory array of FIG. 1A;

FIG. 3A and FIG. 3B depict cross-sectional views of example floating gate memory cells in NAND strings;

FIG. 4A and FIG. 4B depict cross-sectional views of example charge-trapping memory cells in NAND strings;

FIG. 5 depicts an example block diagram of the sense block SB1 of FIG. 1;

FIG. 6A is a perspective view of a set of blocks in an example three-dimensional configuration of the memory array of FIG. 1;

FIG. 6B depicts an example cross-sectional view of a portion of one of the blocks of FIG. 6A;

FIG. 6C depicts a plot of memory hole diameter in the stack of FIG. 6B;

FIG. 6D depicts a close-up view of region 622 of the stack of FIG. 6B;

FIG. 7A depicts a top view of an example word line layer WL0 of the stack of FIG. 6B;

FIG. 7B depicts a top view of an example top dielectric layer DL116 of the stack of FIG. 6B;

FIG. 8 depicts a threshold voltage distribution of a page of memory cells programmed to one bit per memory cell (SLC);

FIG. 9 depicts a threshold voltage distribution of a page of memory cells programmed to three bits per memory cell (TLC);

FIG. 10 depicts a voltage waveform applied to a selected word line during an example programming operation where the memory cells of the selected word line are programmed to multiple bits of data per memory cell;

FIG. 11 is a schematic view illustrating a memory block that has been divided into two lateral sub-blocks;

FIG. 12 is a plot of voltages applied to the word lines of an example memory block during a program-verify operation of one program loop and a programming pulse of an ensuing program loop according to an aspect of the present disclosure;

FIG. 13 is a plot of boosting potential versus word line for two memory blocks, one of which is operating in a normal block mode and the other of which is operating in a lateral sub-block mode and utilizing an exemplary embodiment of the programming techniques of the present disclosure;

FIG. 14 is a flow chart depicting the steps of programming a selected word line according to an exemplary embodiment of the present disclosure;

FIG. 15 is a flow chart depicting the steps of programming a selected word line according to another exemplary embodiment of the present disclosure; and

FIG. 16 is a plot of boosting potential versus word line for three memory blocks, one of which is operating in a normal block mode; a second of which is operating in a lateral sub-block mode and utilizing a first exemplary embodiment of the programming techniques of the present disclosure; and a third of which is operating in a lateral sub-block mode and utilizing a second exemplary embodiment of the programming techniques of the present disclosure.

### DESCRIPTION OF THE ENABLING EMBODIMENTS

As discussed in further detail below, the present disclosure is related generally to programming techniques that allow the channels in a memory block to more effectively be pre-charged while the memory block is operating in a lateral sub-block mode. These programming techniques include a unique ramp down scheme at the end of a program-verify operation and then a unique ramp up scheme at the beginning of a following programming pulse. These ramp down and ramp up schemes pre-charge the channels in an efficient manner without upsetting any data that might be already programmed into the other sub-blocks that are not being programmed.

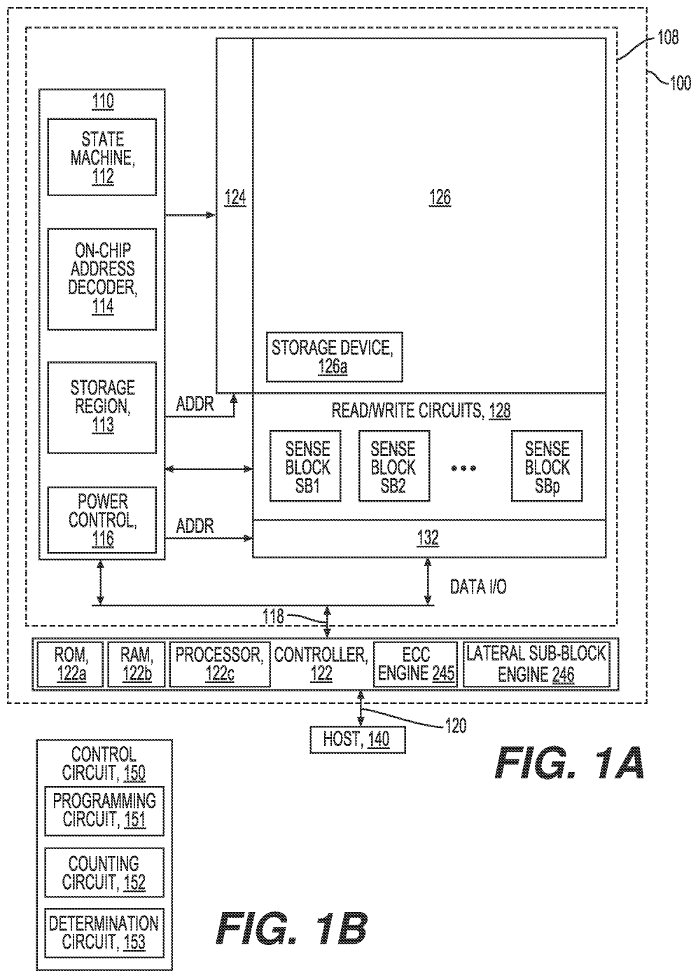

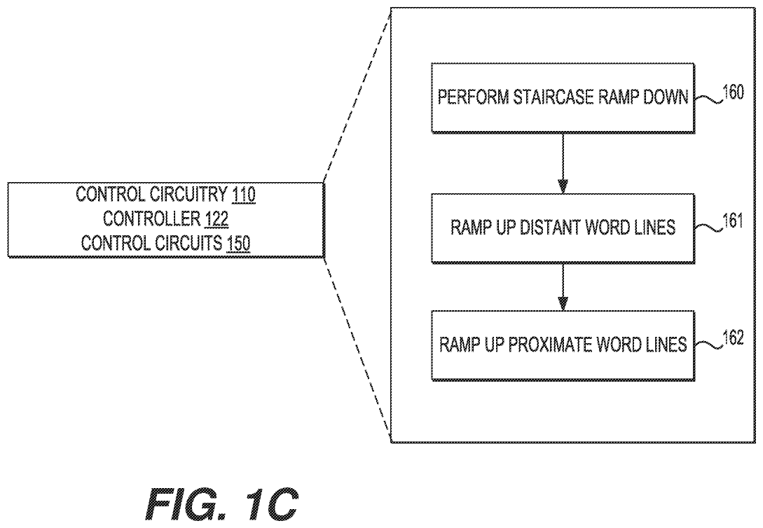

FIG. 1A is a block diagram of an example memory device 100 is configured to program the memory cells in the word lines of a memory block that is operating in a lateral sub-block mode according to the programming techniques of the subject disclosure. The memory die 108 includes a memory structure 126 of memory cells, such as an array of memory cells, control circuitry 110, and read/write circuits 128. The memory structure 126 is addressable by word lines via a row decoder 124 and by bit lines via a column decoder 132. The read/write circuits 128 include multiple sense blocks SB1, SB2, . . . . SBp (sensing circuitry) and allow a page of memory cells to be read or programmed in parallel. Typically, a controller 122 is included in the same memory device 100 (e.g., a removable storage card) as the one or more memory die 108. Commands and data are transferred between the host 140 and controller 122 via a data bus 120, and between the controller and the one or more memory die 108 via lines 118.

The memory structure 126 can be two-dimensional or three-dimensional. The memory structure 126 may comprise one or more array of memory cells including a three-dimensional array. The memory structure 126 may comprise a monolithic three-dimensional memory structure in which multiple memory levels are formed above (and not in) a single substrate, such as a wafer, with no intervening substrates. The memory structure 126 may comprise any type of non-volatile memory that is monolithically formed in one or more physical levels of arrays of memory cells having an active area disposed above a silicon substrate. The memory structure 126 may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations.

A storage region 113 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 114 provides an address interface between that used by the host or a memory controller to the hardware address used by the decoders 124 and 132. The power control module 116 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 126, can be thought of as at least one control circuit which is configured to perform the actions described herein. For example, a control circuit may include any one of, or a combination of, control circuitry 110, state machine 112, decoders 114/132, power control module 116, sense blocks SBb, SB2, . . . , SBp, read/write circuits 128, controller 122, and so forth.

The control circuits 150 can include a programming circuit 151 configured to perform a program and verify operation for one set of memory cells, wherein the one set of memory cells comprises memory cells assigned to represent one data state among a plurality of data states and memory cells assigned to represent another data state among the plurality of data states; the program and verify operation comprising a plurality of program and verify iterations; and in each program and verify iteration, the programming circuit performs programming for the one selected word line after which the programming circuit applies a verification signal to the selected word line. The control circuits 150 can also include a counting circuit 152 configured to obtain a count of memory cells which pass a verify test for the one data state. The control circuits 150 can also include a determination circuit 153 configured to determine, based on an amount by which the count exceeds a threshold, if a programming operation is completed.

For example, FIG. 1B is a block diagram of an example control circuit 150 which comprises the programming circuit 151, the counting circuit 152, and the determination circuit 153.

The off-chip controller 122 may comprise a processor 122c, storage devices (memory) such as ROM 122a and RAM 122b, an error-correction code (ECC) engine 245, and a lateral sub-block programming engine 246. The ECC engine can correct a number of read errors which are caused when the upper tail of a Vt distribution becomes too high. However, uncorrectable errors may exist in some cases. The techniques provided herein reduce the likelihood of uncorrectable errors.

The storage device(s) 122a, 122b comprise, code such as a set of instructions, and the processor 122c is operable to execute the set of instructions to provide the functionality described herein. Alternately or additionally, the processor 122c can access code from a storage device 126a of the memory structure 126, such as a reserved area of memory cells in one or more word lines. For example, code can be used by the controller 122 to access the memory structure 126 such as for programming, read and erase operations. The code can include boot code and control code (e.g., set of instructions). The boot code is software that initializes the controller 122 during a booting or startup process and enables the controller 122 to access the memory structure 126. The code can be used by the controller 122 to control one or more memory structures 126. Upon being powered up, the processor 122c fetches the boot code from the ROM 122a or storage device 126a for execution, and the boot code initializes the system components and loads the control code into the RAM 122b. Once the control code is loaded into the RAM 122b, it is executed by the processor 122c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below. For example, as illustrated in FIG. 1C, the control circuitry 110, controller 122, control circuits 150, and/or any other circuitry are configured/programmed, to perform a unique a programming operation that allows the channels in a selected sub-block to be more efficiently pre-charged. At step 160, the operation includes the step of performing a stair-case ramp down procedure, which involves at the end of a program-verify operation, sequentially ramping down the word lines from a selected word line being programmed towards both ends of the memory block. At step 161, the operation includes the step of ramping up a plurality of distant unselected word lines, e.g., the word lines that are at least four word lines away from the selected word line. At step 162, the operation continues with the step of ramping up proximate word lines, which include the selected word line and the unselected word lines that are adjacent the selected word line.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x- and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

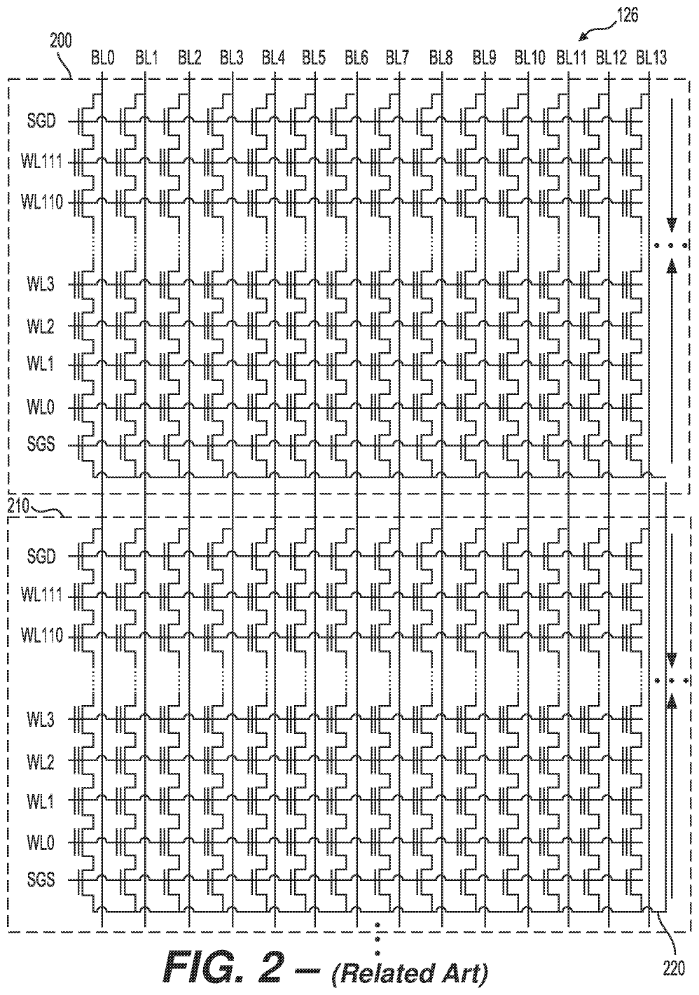

FIG. 2 illustrates memory blocks 200, 210 of memory cells in an example two-dimensional configuration of the memory array 126 of FIG. 1. The memory array 126 can include many such blocks 200, 210. Each example block 200, 210 includes a number of NAND strings and respective bit lines, e.g., BL0, BL1, . . . which are shared among the blocks. Each NAND string is connected at one end to a drain-side select gate (SGD), and the control gates of the drain-side select gates are connected via a common SGD line. The NAND strings are connected at their other end to a source-side select gate (SGS) which, in turn, is connected to a common source line 220. One hundred and twelve word lines, for example, WL0-WL111, extend between the SGSs and the SGDs. In some embodiments, the memory block may include more or fewer than one hundred and twelve word lines. For example, in some embodiments, a memory block includes one hundred and sixty-four word lines. In some cases, dummy word lines, which contain no user data, can also be used in the memory array adjacent to the select gate transistors or between certain data word lines. Such dummy word lines can shield the edge data word line from certain edge effects.

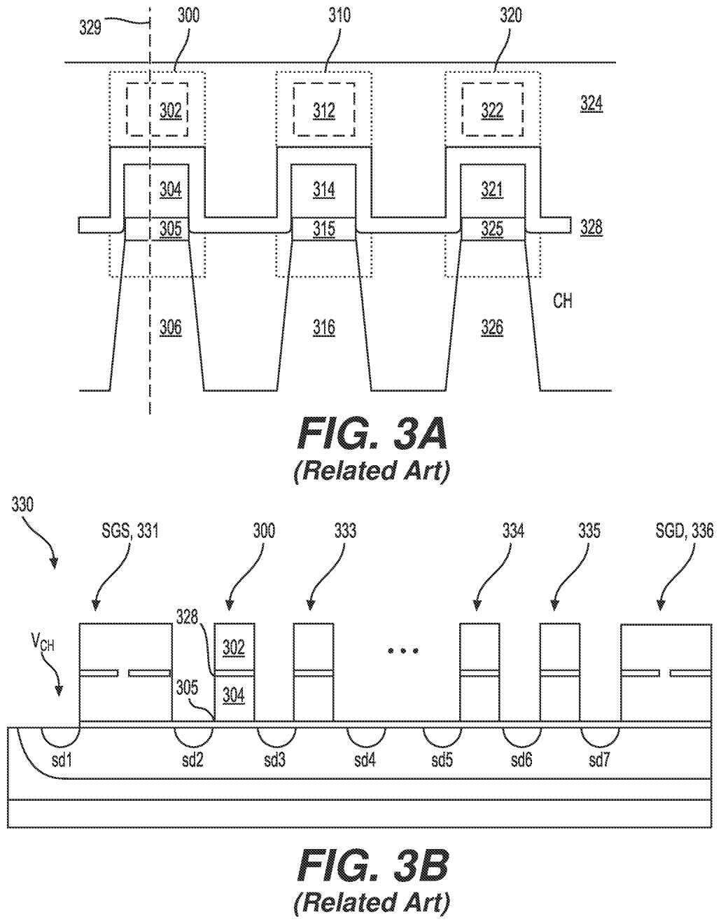

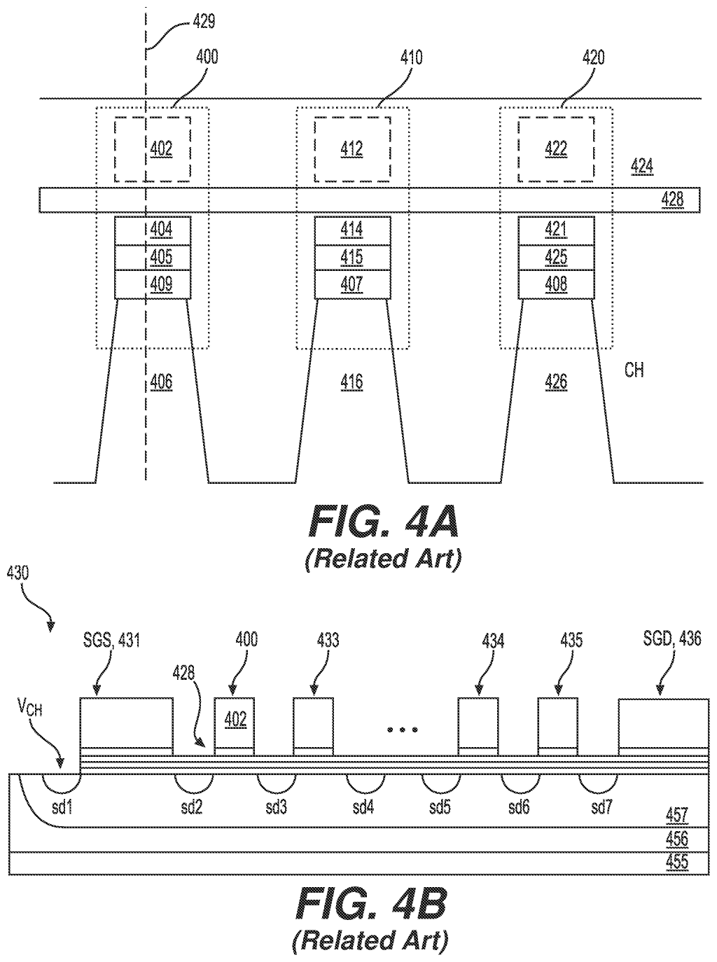

One type of non-volatile memory which may be provided in the memory array is a floating gate memory, such as of the type shown in FIGS. 3A and 3B. However, other types of non-volatile memory can also be used. As discussed in further detail below, in another example shown in FIGS. 4A and 4B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 3A illustrates a cross-sectional view of example floating gate memory cells 300, 310, 320 in NAND strings. In this Figure, a bit line or NAND string direction goes into the page, and a word line direction goes from left to right. As an example, word line 324 extends across NAND strings which include respective channel regions 306, 316 and 326. The memory cell 300 includes a control gate 302, a floating gate 304, a tunnel oxide layer 305 and the channel region 306. The memory cell 310 includes a control gate 312, a floating gate 314, a tunnel oxide layer 315 and the channel region 316. The memory cell 320 includes a control gate 322, a floating gate 321, a tunnel oxide layer 325 and the channel region 326. Each memory cell 300, 310, 320 is in a different respective NAND string. An inter-poly dielectric (IPD) layer 328 is also illustrated. The control gates 302, 312, 322 are portions of the word line. A cross-sectional view along contact line connector 329 is provided in FIG. 3B.

The control gate 302, 312, 322 wraps around the floating gate 304, 314, 321, increasing the surface contact area between the control gate 302, 312, 322 and floating gate 304, 314, 321. This results in higher IPD capacitance, leading to a higher coupling ratio which makes programming and erase easier. However, as NAND memory devices are scaled down, the spacing between neighboring cells 300, 310, 320 becomes smaller so there is almost no space for the control gate 302, 312, 322 and the IPD layer 328 between two adjacent floating gates 302, 312, 322.

As an alternative, as shown in FIGS. 4A and 4B, the flat or planar memory cell 400, 410, 420 has been developed in which the control gate 402, 412, 422 is flat or planar; that is, it does not wrap around the floating gate and its only contact with the charge storage layer 428 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 4A depicts a cross-sectional view of example charge-trapping memory cells 400, 410, 420 in NAND strings. The view is in a word line direction of memory cells 400, 410, 420 comprising a flat control gate and charge-trapping regions as a two-dimensional example of memory cells 400, 410, 420 in the memory cell array 126 of FIG. 1. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 424 extends across NAND strings which include respective channel regions 406, 416, 426. Portions of the word line provide control gates 402, 412, 422. Below the word line is an IPD layer 428, charge-trapping layers 404, 414, 421, polysilicon layers 405, 415, 425, and tunneling layers 409, 407, 408. Each charge-trapping layer 404, 414, 421 extends continuously in a respective NAND string. The flat configuration of the control gate can be made thinner than a floating gate. Additionally, the memory cells can be placed closer together.

FIG. 4B illustrates a cross-sectional view of the structure of FIG. 4A along contact line connector 429. The NAND string 430 includes an SGS transistor 431, example memory cells 400, 433, . . . 435, and an SGD transistor 436. Passageways in the IPD layer 428 in the SGS and SGD transistors 431, 436 allow the control gate layers 402 and floating gate layers to communicate. The control gate 402 and floating gate layers may be polysilicon and the tunnel oxide layer may be silicon oxide, for instance. The IPD layer 428 can be a stack of nitrides (N) and oxides (O) such as in a N—O—N—O—N configuration.

The NAND string may be formed on a substrate which comprises a p-type substrate region 455, an n-type well 456 and a p-type well 457. N-type source/drain diffusion regions sd1, sd2, sd3, sd4, sd5, sd6 and sd7 are formed in the p-type well. A channel voltage, Vch, may be applied directly to the channel region of the substrate.

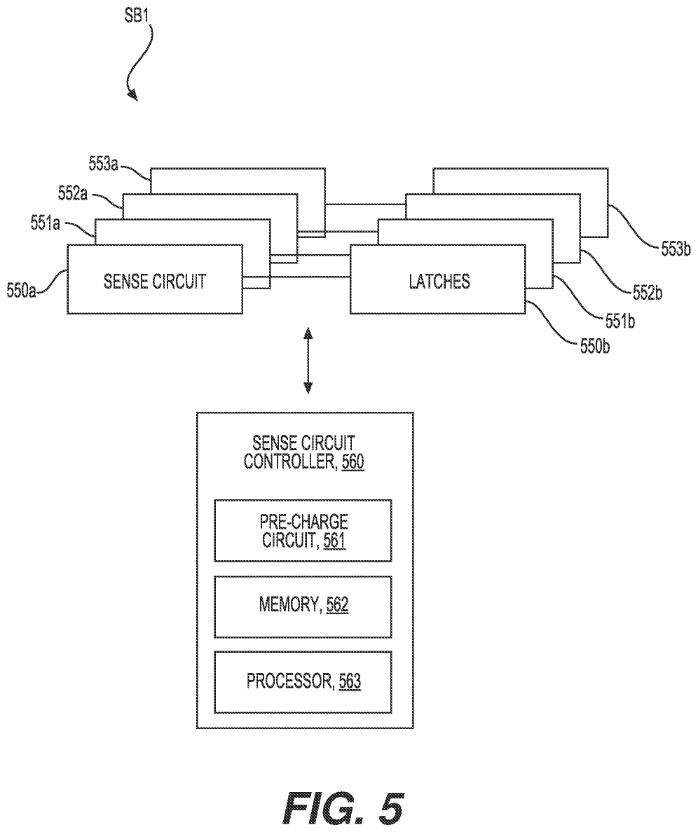

FIG. 5 illustrates an example block diagram of the sense block SB1 of FIG. 1. In one approach, a sense block comprises multiple sense circuits. Each sense circuit is associated with data latches. For example, the example sense circuits 550a, 551a, 552a, and 553a are associated with the data latches 550b, 551b, 552b, and 553b, respectively. In one approach, different subsets of bit lines can be sensed using different respective sense blocks. This allows the processing load which is associated with the sense circuits to be divided up and handled by a respective processor in each sense block. For example, a sense circuit controller 560 in SB1 can communicate with the set of sense circuits and latches. The sense circuit controller 560 may include a pre-charge circuit 561 which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 560 may also include a pre-charge circuit 561, a memory 562 and a processor 563. The memory 562 may store code which is executable by the processor to perform the functions described herein. These functions can include reading the latches 550b, 551b, 552b, 553b which are associated with the sense circuits 550a, 551a, 552a, 553a, setting bit values in the latches and providing voltages for setting pre-charge levels in sense nodes of the sense circuits 550a, 551a, 552a, 553a. Further example details of the sense circuit controller 560 and the sense circuits 550a, 551a, 552a, 553a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

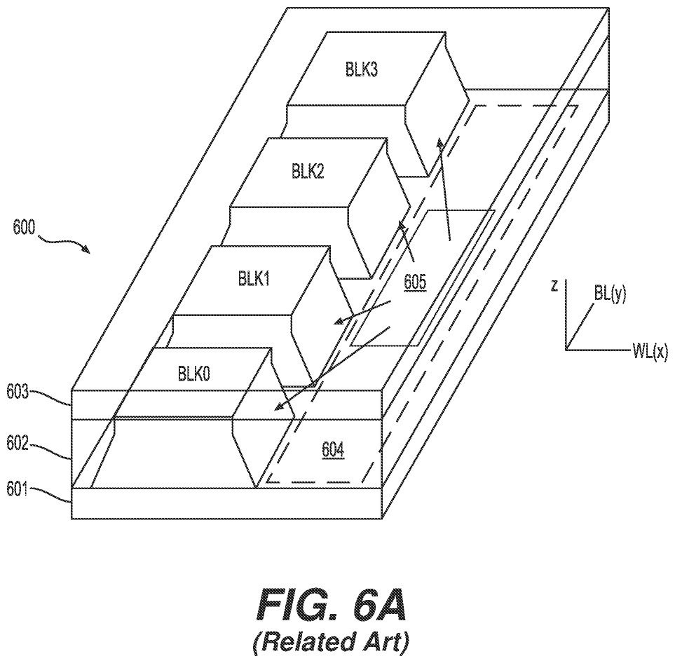

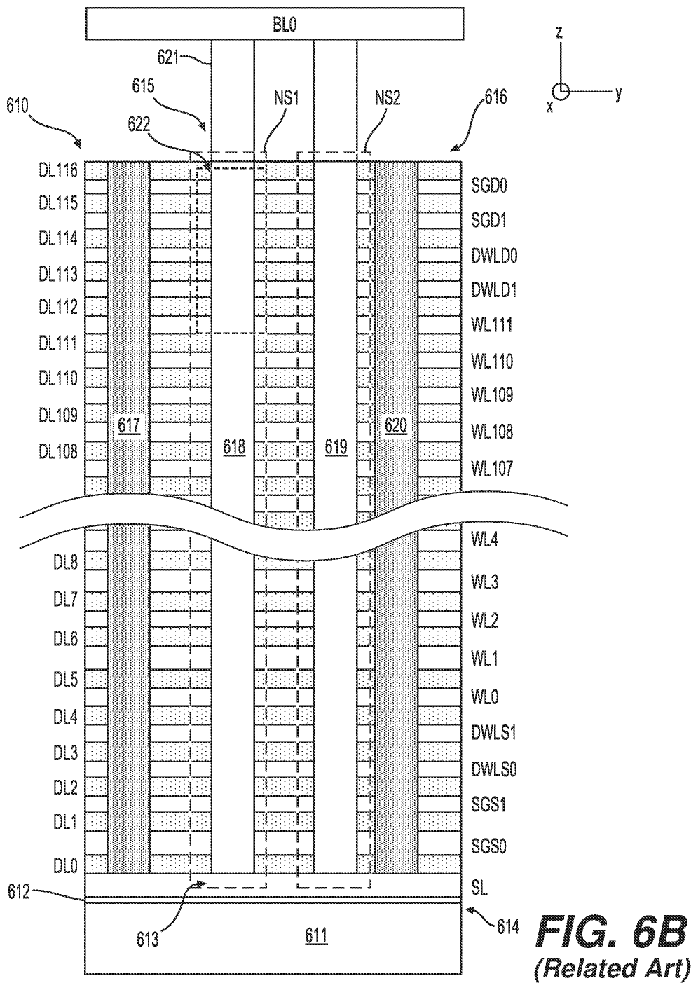

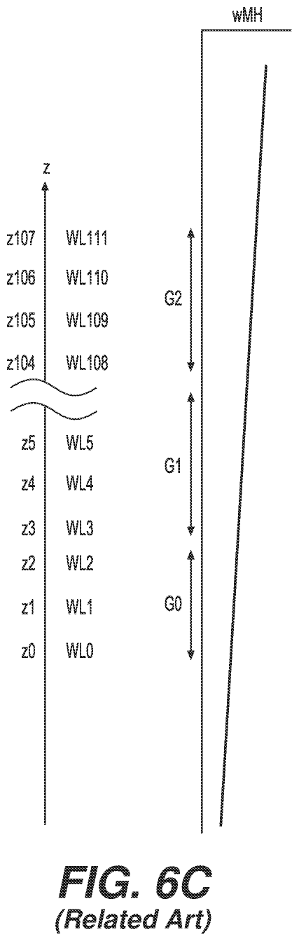

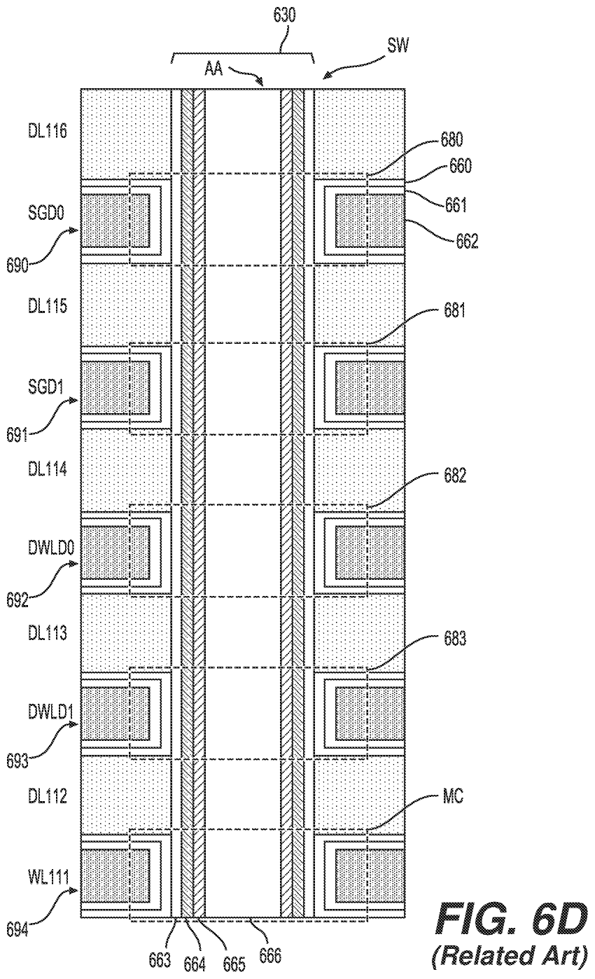

FIG. 6A is a perspective view of a set of blocks 600 in an example three-dimensional configuration of the memory array 126 of FIG. 1. On the substrate are example blocks BLK0, BLK1, BLK2, BLK3 of memory cells (storage elements) and a peripheral area 604 with circuitry for use by the blocks BLK0, BLK1, BLK2, BLK3. For example, the circuitry can include voltage drivers 605 which can be connected to control gate layers of the blocks BLK0, BLK1, BLK2, BLK3. In one approach, control gate layers at a common height in the blocks BLK0, BLK1, BLK2, BLK3 are commonly driven. The substrate 601 can also carry circuitry under the blocks BLK0, BLK1, BLK2, BLK3, along with one or more lower metal layers which are patterned in conductive paths to carry signals of the circuitry. The blocks BLK0, BLK1, BLK2, BLK3 are formed in an intermediate region 602 of the memory device. In an upper region 603 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, BLK3 are illustrated as an example, two or more blocks can be used, extending in the x- and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 6B illustrates an example cross-sectional view of a portion of one of the blocks BLK0, BLK1, BLK2, BLK3 of FIG. 6A. The block comprises a stack 610 of alternating conductive and dielectric layers. In this example, the conductive layers comprise two SGD layers, two SGS layers and four dummy word line layers DWLD0, DWLD1, DWLS0 and DWLS1, in addition to data word line layers (word lines) WL0-WL111. The dielectric layers are labelled as DL0-DL116. Further, regions of the stack 610 which comprise NAND strings NS1 and NS2 are illustrated. Each NAND string encompasses a memory hole 618, 619 which is filled with materials which form memory cells adjacent to the word lines. A region 622 of the stack 610 is shown in greater detail in FIG. 6D and is discussed in further detail below. The dielectric layers can have variable thicknesses such that some of the conductive layers can be closer to or further from neighboring conductive layers. The thicknesses of the dielectric layers affects the “ON pitch,” which is a factor in memory density. Specifically, a smaller ON pitch allows for more memory cells in a given area but may compromise reliability.

The stack 610 includes a substrate 611, an insulating film 612 on the substrate 611, and a portion of a source line SL. NS1 has a source-end 613 at a bottom 614 of the stack and a drain-end 615 at a top 616 of the stack 610. Contact line connectors (e.g., slits, such as metal-filled slits) 617, 620 may be provided periodically across the stack 610 as interconnects which extend through the stack 610, such as to connect the source line to a particular contact line above the stack 610. The contact line connectors 617, 620 may be used during the formation of the word lines and subsequently filled with metal. A portion of a bit line BL0 is also illustrated. A conductive via 621 connects the drain-end 615 to BL0.

FIG. 6C illustrates a plot of memory hole diameter in the stack of FIG. 6B. The vertical axis is aligned with the stack of FIG. 6B and illustrates a width (wMH), e.g., diameter, of the memory holes 618 and 619. The word line layers WL0-WL111 of FIG. 6A are repeated as an example and are at respective heights z0-z111 in the stack. In such a memory device, the memory holes which are etched through the stack have a very high aspect ratio. For example, a depth-to-diameter ratio of about 25-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

FIG. 6D illustrates a close-up view of the region 622 of the stack 610 of FIG. 6B. Memory cells are formed at the different levels of the stack at the intersection of a word line layer and a memory hole. In this example, SGD transistors 680, 681 are provided above dummy memory cells 682, 683 and a data memory cell MC. A number of layers can be deposited along the sidewall (SW) of the memory hole 630 and/or within each word line layer, e.g., using atomic layer deposition. For example, each column (e.g., the pillar which is formed by the materials within a memory hole 630) can include a charge-trapping layer or film 663 such as SiN or other nitride, a tunneling layer 664, a polysilicon body or channel 665, and a dielectric core 666. A word line layer can include a blocking oxide/block high-k material 660, a metal barrier 661, and a conductive metal such as Tungsten as a control gate. For example, control gates 690, 691, 692, 693, and 694 are provided. In this example, all of the layers except the metal are provided in the memory hole 630. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer which is associated with the memory cell. These electrons are drawn into the charge-trapping layer from the channel and through the tunneling layer. The threshold voltage Vt of a memory cell is increased in proportion to the amount of stored charge. During a sensing operation, the threshold voltage Vt is detected or measured. During an erase operation, the electrons return to the channel.

Each of the memory holes 630 can be filled with a plurality of annular layers comprising a blocking oxide layer, a charge trapping layer 663, a tunneling layer 664 and a channel layer. A core region of each of the memory holes 630 is filled with a body material, and the plurality of layers are between the core region and the word line layer in each of the memory holes 630. In some cases, the charge trapping layer 663 and the tunneling layer 664 are annular in shape. In other cases, as discussed in further detail below, these layers are semi-circular in shape.

The NAND string can be considered to have a floating body channel because the length of the channel is not formed on a substrate. Further, the NAND string is provided by a plurality of word line layers above one another in a stack, and separated from one another by dielectric layers.

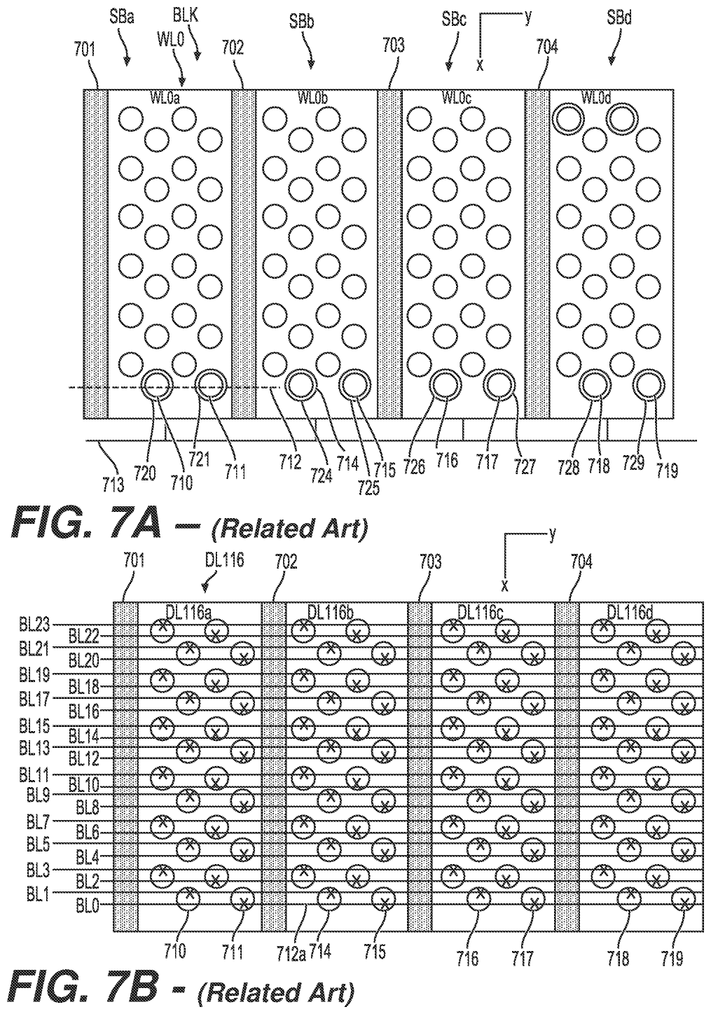

FIG. 7A illustrates a top view of an example word line layer WL0 of the stack 610 of FIG. 6B. As mentioned, a three-dimensional memory device can comprise a stack of alternating conductive and dielectric layers. The conductive layers provide the control gates of the SG transistors and memory cells. The layers used for the SG transistors are SG layers and the layers used for the memory cells are word line layers. Further, memory holes are formed in the stack and filled with a charge-trapping material and a channel material. As a result, a vertical NAND string is formed. Source lines are connected to the NAND strings below the stack and bit lines are connected to the NAND strings above the stack.

A block BLK in a three-dimensional memory device can be divided into sub-blocks, where each sub-block comprises a NAND string group which has a common SGD control line. For example, see the SGD lines/control gates SGD0, SGD1, SGD2 and SGD3 in the sub-blocks SBa, SBb, SBc and SBd, respectively. Further, a word line layer in a block can be divided into regions. Each region is in a respective sub-block and can extend between contact line connectors (e.g., slits) which are formed periodically in the stack to process the word line layers during the fabrication process of the memory device. This processing can include replacing a sacrificial material of the word line layers with metal. Generally, the distance between contact line connectors should be relatively small to account for a limit in the distance that an etchant can travel laterally to remove the sacrificial material, and that the metal can travel to fill a void which is created by the removal of the sacrificial material. For example, the distance between contact line connectors may allow for a few rows of memory holes between adjacent contact line connectors. The layout of the memory holes and contact line connectors should also account for a limit in the number of bit lines which can extend across the region while each bit line is connected to a different memory cell. After processing the word line layers, the contact line connectors can optionally be filed with metal to provide an interconnect through the stack.

In this example, there are four rows of memory holes between adjacent contact line connectors. A row here is a group of memory holes which are aligned in the x-direction. Moreover, the rows of memory holes are in a staggered pattern to increase the density of the memory holes. The word line layer or word line is divided into regions WL0a, WL0b, WL0c and WL0d which are each connected by a contact line 713. The last region of a word line layer in a block can be connected to a first region of a word line layer in a next block, in one approach. The contact line 713, in turn, is connected to a voltage driver for the word line layer. The region WL0a has example memory holes 710, 711 along a contact line 712. The region WL0b has example memory holes 714, 715. The region WL0c has example memory holes 716, 717. The region WL0d has example memory holes 718, 719. The memory holes are also shown in FIG. 7B. Each memory hole can be part of a respective NAND string. For example, the memory holes 710, 714, 716 and 718 can be part of NAND strings NS0_SBa, NS1_SBb, NS2_SBc, NS3_SBd, and NS4_SBe, respectively.

Each circle represents the cross-section of a memory hole at a word line layer or SG layer. Example circles shown with dashed lines represent memory cells which are provided by the materials in the memory hole and by the adjacent word line layer. For example, memory cells 720, 721 are in WL0a, memory cells 724, 725 are in WL0b, memory cells 726, 727 are in WL0c, and memory cells 728, 729 are in WL0d. These memory cells are at a common height in the stack.

Contact line connectors (e.g., slits, such as metal-filled slits) 701, 702, 703, 704 may be located between and adjacent to the edges of the regions WL0a-WL0d. The contact line connectors 701, 702, 703, 704 provide a conductive path from the bottom of the stack to the top of the stack. For example, a source line at the bottom of the stack may be connected to a conductive line above the stack, where the conductive line is connected to a voltage driver in a peripheral region of the memory device.

FIG. 7B illustrates a top view of an example top dielectric layer DL116 of the stack of FIG. 6B. The dielectric layer is divided into regions DL116a, DL116b, DL116c and DL116d. Each region can be connected to a respective voltage driver. This allows a set of memory cells in one region of a word line layer being programmed concurrently, with each memory cell being in a respective NAND string which is connected to a respective bit line. A voltage can be set on each bit line during each programming, sensing, or erasing operation.

The region DL116a has the example memory holes 710, 711 along a contact line 712, which is coincident with a bit line BL0. A number of bit lines extend above the memory holes and are connected to the memory holes as indicated by the “X” symbols. BL0 is connected to a set of memory holes which includes the memory holes 711, 715, 717, 719. Another example bit line BL1 is connected to a set of memory holes which includes the memory holes 710, 714, 716, 718. The contact line connectors (e.g., slits, such as metal-filled slits) 701, 702, 703, 704 from FIG. 7A are also illustrated, as they extend vertically through the stack. The bit lines can be numbered in a sequence BL0-BL23 across the DL116 layer in the x-direction.

Different subsets of bit lines are connected to memory cells in different rows. For example, BL0, BL4, BL8, BL12, BL16, BL20 are connected to memory cells in a first row of cells at the right-hand edge of each region. BL2, BL6, BL10, BL14, BL18, BL22 are connected to memory cells in an adjacent row of cells, adjacent to the first row at the right-hand edge. BL3, BL7, BL11, BL15, BL19, BL23 are connected to memory cells in a first row of cells at the left-hand edge of each region. BL1, BL5, BL9, BL13, BL17, BL21 are connected to memory cells in an adjacent row of memory cells, adjacent to the first row at the left-hand edge.

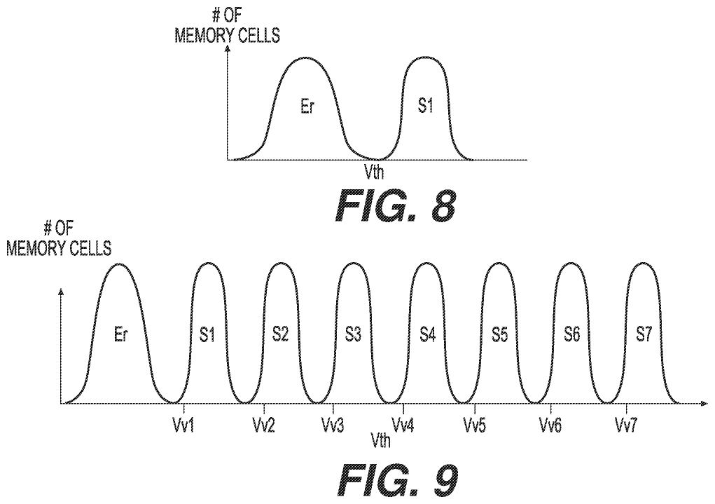

The memory cells of the memory blocks can be programmed to store one or more bits of data in multiple data states, each of which is associated with a respective threshold voltage Vt range and with a respective bit or series of bits. For example, FIG. 8 depicts a threshold voltage Vt distribution of a group of memory cells programmed according to a one bit per memory cell (SLC) storage scheme. In the SLC storage scheme, there are two total data states, including the erased state (Er) and a single programmed data state (S1). FIG. 9 illustrates the threshold voltage Vt distribution of a three bits per cell (TLC) storage scheme that includes eight total data states, namely the erased state (Er) and seven programmed data states (S1, S2, S3, S4, S5, S6, and S7). Each programmed data state (S1-S7) is associated with a respective verify voltage (Vv1-Vv7), which is employed during a verify portion of a programming operation. Similarly, each programmed data state is associated with a unique read voltage that can be the same or different than the respective verify voltages. Other storage schemes are also available, such as two bits per cell (MLC) with four data states, four bits per cell (QLC) with sixteen data states, or five bits per cell (PLC) with thirty-two data states.

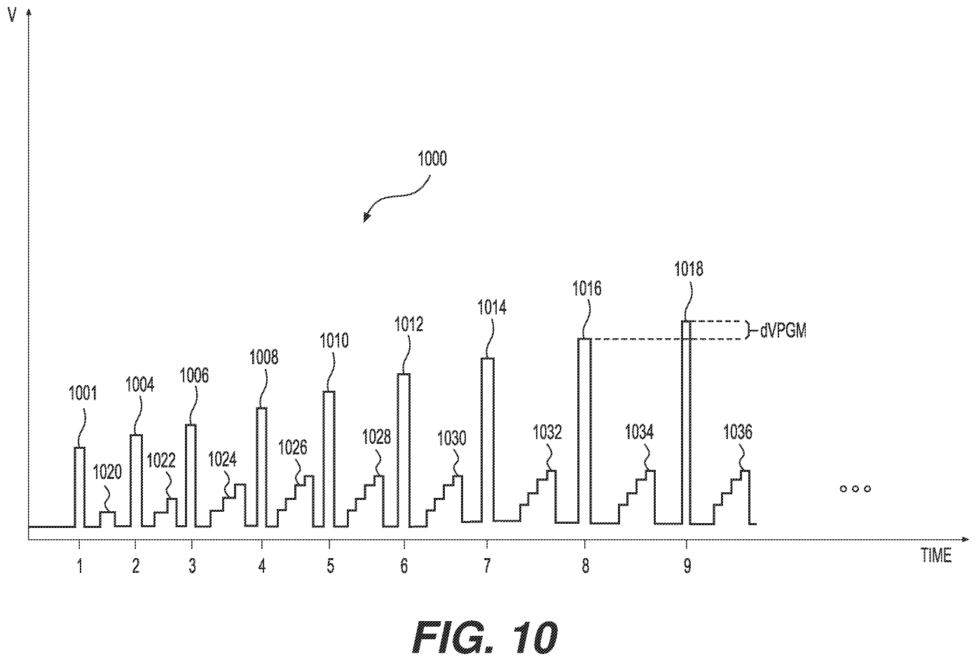

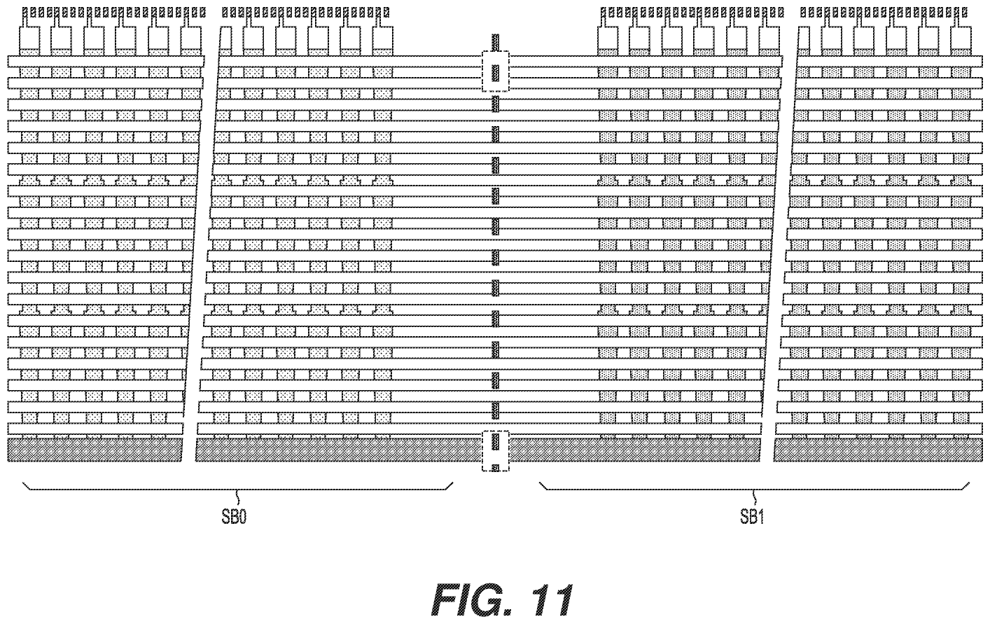

Programming the memory cells occurs on a word line-by-word line basis from one side of the memory block towards an opposite side of the memory block. In contrast, erase typically occurs on a block or sub-block basis. Typically, programming the memory cells of a selected word line to retain multiple bits per memory cell (for example, MLC, TLC, or QLC) starts with the memory cells being in the erased data state and includes a plurality of program loops. Each program loop includes both a programming pulse and a verify operation. FIG. 10 depicts a waveform 1000 of the voltages applied to a selected word line WLn during an example programming operation for programming the memory cells of the selected word line WLn to a greater number of bits per memory cell (e.g., TLC or QLC). As depicted, each program loop includes a programming pulse (hereinafter referred to as a VPGM pulse 1001-1018) and one or more verify pulses 1020-1036, depending on which data states are being programmed in a particular program loop. During each VPGM pulse, the unselected word lines in the memory block are also ramped to a pass voltage VPASS to prevent unintentional programming of the memory cells in the unselected word lines.

During the program-verify portion, a reference voltage VCG is applied to the selected word line WLn and pass voltages VREAD are applied to all of the unselected word lines. and a current is discharged through the NAND strings that contain the memory cells to be sensed. Since the memory cells of the unselected word lines are “turned on” (made conductive to electrons) by the pass voltages VREAD, the current in the NAND string is largely dictated by the relationship between the threshold voltage Vt of the memory cell being sensed and the reference voltage VCG. If the current is relatively high, then the memory cell is “on” and its threshold voltage Vt is less than the reference voltage VCG. On the other hand, if the current is relatively low, then the memory cell is “off” and its threshold voltage Vt is greater than the reference voltage VCG.

In between the program-verify portion of one program loop and the VPGM pulse of a next program loop, the channels of the memory block are preferably pre-charged to remove electrons from the areas of the channels adjacent the selected word line WLn.

While programming occurs on a word line level (the memory cells of one word line are programmed at a time), erase often occurs on a memory block level or a sub-block level. In other words, when data stored in the memory cells of some word lines of a memory block is no longer needed, before new data can be programmed to those memory cells, all of the memory cells in the memory block must first be erased together. In other words, if data is programmed into two sub-blocks of a memory block and it is desired to only erase the data in one of the sub-blocks, then the other sub-block can remain programmed during the erase operation. This is in contrast to “normal block” mode where all of the word lines of the memory block must be erased together.

One way to divide the memory cells into a pair of sub-blocks is to divide the word lines vertically into two or more multiple sub-blocks. For example, with reference to FIG. 6B, word lines WL0 through WL55 could be in a first sub-block, and word lines WL56 through WL111 could be in a second sub-block. This is sometimes known as “vertical sub-block mode” because the sub-blocks are separated from one another in a vertical direction.

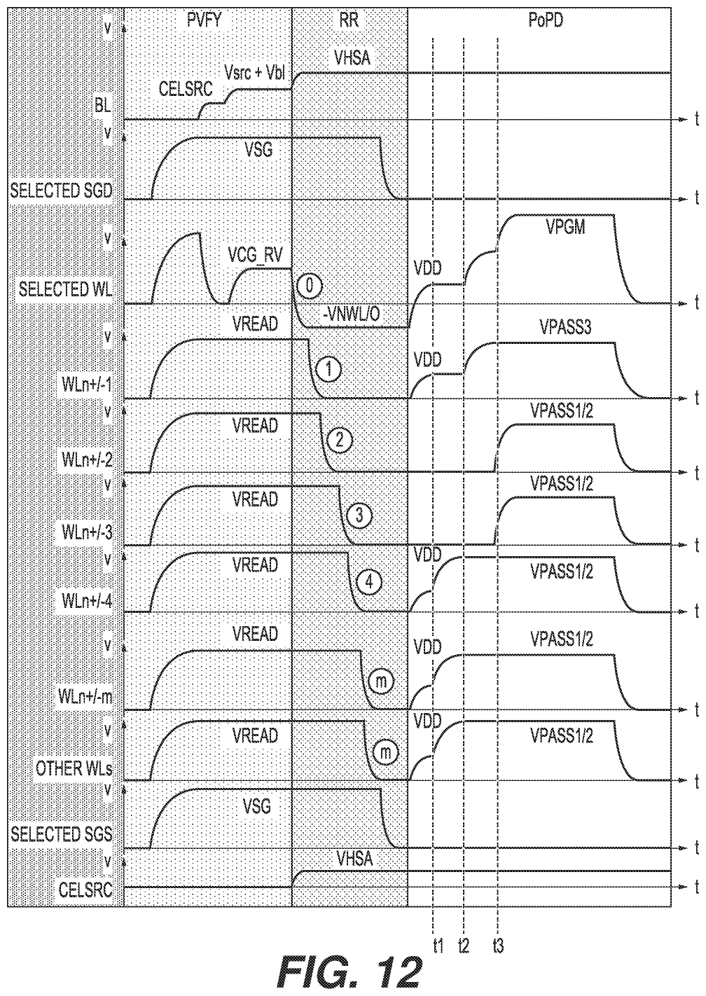

Another option for dividing the memory cells of a memory block into sub-blocks is to divide the memory cells laterally in a “lateral sub-block mode.” For example, with reference to FIG. 7A, a memory block includes four sub-blocks SBa, SBb, SBc, SBd that are divided by strings and are separated from one another by shallow etches (metal filled slits 701, 702, 703, 704). Alternately, FIG. 12 illustrates a situation where the memory cells of a memory block have been divided into two lateral sub-blocks SB0, SB0 by bit line group. Dividing the memory block laterally, rather than vertically, offers some advantages, including reduced current usage, improved CMOS scaling, and improved sub-block uniformity. However, channel boosting is more difficult when a memory block is in the lateral sub-block mode because all of the word lines in the sub-block may already be partially programmed, thereby making pre-charging using conventional pre-charging techniques very difficult or impossible, which could cause program disturb in the already programmed memory cells of the unselected sub-blocks.

According to an aspect of the present disclosure, an improved programming technique is provided to more effectively pre-charge the channels in a memory block that is operating in a lateral sub-block mode. This programming technique includes unique word line discharge and word line ramping processes between the program-verify portion of one program loop and the VPGM pulse of a next program loop.

FIG. 12 illustrates the voltages that are applied to the word lines of a memory block according to an exemplary embodiment of the programming techniques of the present disclosure. Between the program-verify operation of one program loop and the VPGM pulse of a next program loop, the programming techniques include a word line ramp down scheme and then a word line ramp up scheme that have been found to effectively pre-charge the channels of a selected (lateral) sub-block between program loops without impacting programmed data that is contained in the memory cells of any unselected (lateral) sub-blocks.

As illustrated in FIG. 12, at the end of the program-verify pulse, the selected word line WLn is at the reference voltage VCG (which could correspond to any of the verify voltages Vvn illustrated in FIG. 9) and the unselected word lines are all at a pass voltage VREAD. The selected word line WLn is first ramped down or discharged from the reference voltage VCG to a very low voltage, which could be approximately 0 V or a negative voltage −VNWL. Next, only after discharge of the selected word line WLn has begun, the unselected word lines begin to sequentially ramp down from the pass voltage VREAD to approximately 0 V in a step-like fashion from adjacent the selected word line WLn towards the source and drain sides of the memory block until all of the unselected word lines have been ramped down. For example, the unselected word lines WLn−1, WLn+1 on either side of the selected word line WLn are ramped down to approximately 0 V. Then, the only after ramping down of WLn−1, WLn+1 has begun, the unselected word lines WLn−2, WLn+2 are ramped down to approximately 0 V. Next, only after ramping down of WLn−2, WLn+2 has begun, the unselected word lines WLn−3, WLn+3 begin ramping down to approximately 0 V. This stair case-like ramp down pattern that is illustrated in FIG. 12 continues for all of the unselected word lines to squeeze electrons that were in the channels of the memory block during the program-verify operation out of the area of the selected word line WLn.

In the embodiment depicted in FIG. 12, the unselected word lines begin to ramp down two at a time (one on the source side of the selected word line WLn and one on the drain side). However, in an effort to improve performance (i.e., reduce programming time), in some embodiments, some adjacent unselected word lines (e.g., two or three unselected word lines) can begin ramping down together as a group so long as this pattern of first ramping down the unselected word lines near the selected word line WLn and then moving outwardly in each direction away from the selected word line WLn is maintained. For example, after ramping down begins for the selected word line WLn, then ramping down can next simultaneously begin for unselected word lines WLn−3, WLn−2, WLn−1, WLn+1, WLn+2, and WLn+3, and then after that, ramping down can simultaneously begin for unselected word lines WLn−6, WLn−5, WLn−4, WLn+4, WLn+5, and WLn+6, and so on. By ramping down the word lines in groups of more than two word lines, the ramping down process can be shortened and programming performance can be improved. According to presently preferred embodiments, in order to retain adequate channel boosting, no more than six word lines (up to three on each side of the selected word line WLn) should be ramped down together, i.e., each group should include no more than six word lines.

Notably, during the word line ramp down scheme depicted in FIG. 12, only the selected word line WLn is (optionally) ramped down to a negative voltage with all of the unselected word lines being ramped down to no less than 0 V. Thus, this technique can be applied to improve word line boosting in memory devices that are only configured to apply a negative voltage to a single word line at a time. In some embodiments where the memory block is able to apply negative voltages to multiple word lines at a time, then the unselected word lines can be ramped down to less than 0 V. However, this is not necessary to achieve adequate pre-charging.

As also depicted in FIG. 12, the programming technique of the present disclosure also includes a word line ramp up scheme to prevent electrons from flowing into the selected word line WLn regions of the channels prior to the ensuing VPGM pulse. According to this ramp up scheme, at the beginning of the ensuing VPGM pulse process, at time t1, all of the unselected word lines that are distant from the selected word line begin to ramp up from approximately 0 V to their respective pass voltages VPASS1 or VPASS2. The distant word lines include all of the word lines in the memory block except the selected word line WLn and a few unselected word lines that are adjacent the selected word line WLn, e.g., WLn−3, WLn−2, WLn−1, WLn+1, WLn+2, and WLn+3. In this example, at time t1, the selected word line WLn is held at the negative voltage-VNWL or is ramped to only a low voltage VDD, which is substantially lower than the pass voltages VPASS1, VPASS2, and the six closest unselected word lines WLn−3, WLn−2, WLn−1, WLn+1, WLn+2, WLn+3 are also held at approximately 0 V or are ramped to only a low voltage VDD. In some presently preferred embodiments, no more than six unselected word lines are held at approximately 0 V or ramped to only the very low voltage VDD at time t1 when the other unselected word lines begin the ramp up process.

Next, at time t2, the selected word line WLn and the two unselected word lines WLn−1, WLn+1 immediately adjacent the selected word line WLn begin to ramp up to a pass voltage VPASS3. At time t2, the remaining unselected word lines WLn−3, WLn−2, WLn+2, WLn+3 are held at approximately 0 V.

Then, at time t3, the selected word line WLn continues ramping up from the pass voltage VPASS3 to the programming voltage VPGM and the remaining unselected word lines WLn−3, WLn−2, WLn+2, WLn+3 begin ramping up from approximately 0 V to VPASS1 or VPASS 2.

The programming technique depicted in FIG. 12 has been found to prevent electrons from flowing to the selected word line WLn regions of the channels, thereby improving word line boosting. This boosting is effective even in memory blocks that are operating in a lateral sub-block mode without impacting data that may be programmed into the memory cells of the unselected sub-blocks.

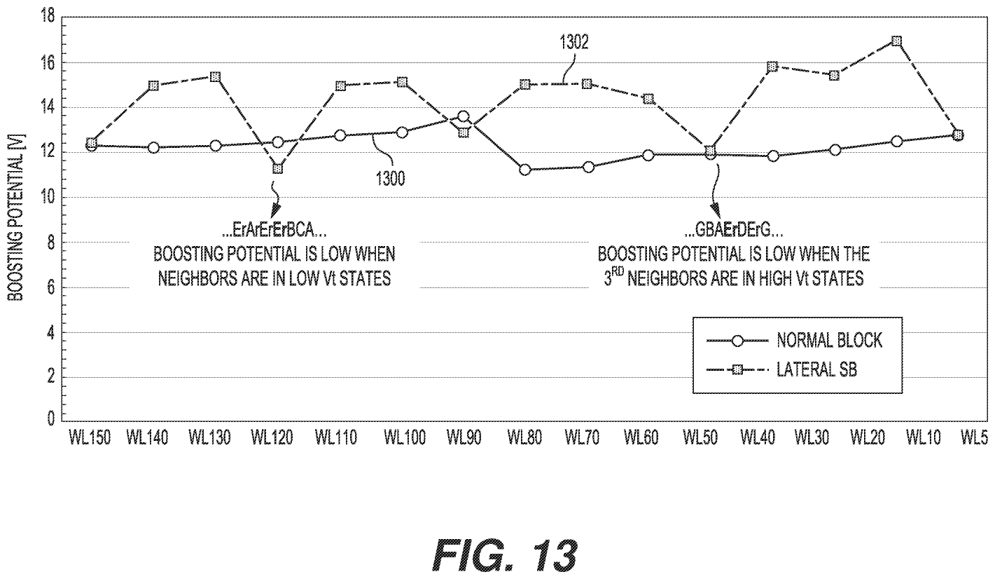

FIG. 13 is a plot of boosting potential versus word line in an exemplary memory block where two different operating modes with pre-charge schemes are employed. Specifically, line 1300 depicts boosting potential where the memory block is operating in a “normal block mode” (no sub-blocks) and with a conventional pre-charging operation, and line 1302 depicts boosting potential where the memory block is operating in a lateral sub-block mode and the programming techniques of the present disclosure are employed. As illustrated, programming techniques of the present disclosure result in generally similar, and often better, boosting potential than the conventional pre-charging operation across most word lines of the memory block.

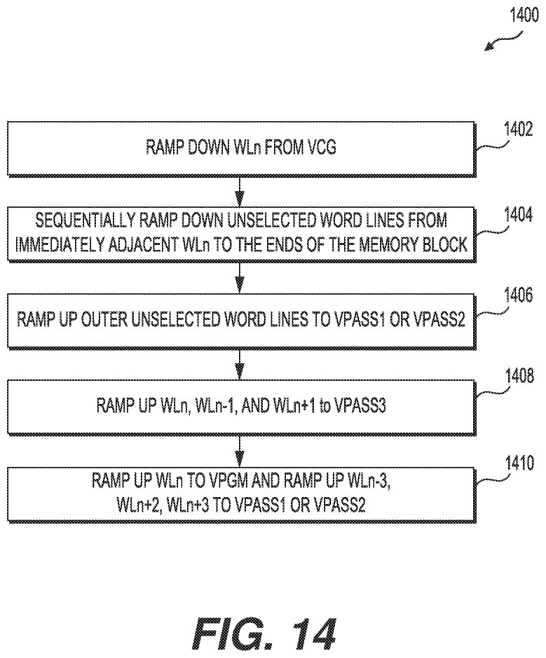

Turning now to FIG. 14, a flow chart 1400 is provided that depicts the steps of performing a word line ramp down process followed by a word line ramp up process according to an example embodiment of the subject disclosure. These steps could be performed by the controller; a processor or processing device or any other circuitry, executing instructions stored in memory; and/or other circuitry described herein that is specifically configured/programmed to execute the following steps.

The following steps begin at the end of a program-verify pulse. At this time, a reference voltage VCG is being applied to a selected word line WLn and pass voltages VREAD are being applied to the unselected word lines on either side of the selected word line WLn. At step 1402, the selected word line WLn is ramped down from the reference voltage VCG to either a negative voltage-VNWL or approximately 0 V. At step 1404, the unselected word lines are sequentially ramped down from the pass voltages VREAD to approximately 0 V (or a negative voltage if the memory block is able to apply negative voltages to multiple word lines simultaneously). More specifically, the unselected word lines that are immediately adjacent (on the drain side and source side of) the selected word line WLn are ramped down first and then the word lines that are next closest to the selected word line WLn and then the word lines that are next closest after that and so on until all of the word lines in the memory block have been ramped down. As discussed above, in some embodiments, the unselected word lines can be ramped down in groups, e.g., four to six word lines at a time. Once the unselected word lines have finished ramping down, the next program loop is ready to begin.

At step 1406, the outer unselected word lines are ramped up to their respective pass voltages VPASS1, VPASS2. The outer unselected word lines include all of the unselected word lines that are distant from the selected word line WLn. For example, in one embodiment, the outer word lines include all of the word lines that are four or more word lines away from the selected word line WLn, i.e., WL0 through WLn−4 and WLn+4 through WLN where “N” is the last word line in the memory block.

At step 1408, the selected word line WLn and the two immediately adjacent word lines WLn−1, WLn+1 are ramped up to the pass voltage VPASS3. Finally, at step 1410, the selected word line WLn is ramped up further from VPASS3 to the programming voltage VPGM and the remaining unselected word lines WLn−3, WLn−2, WLn+2, WLn+3 are ramped up to their respective pass voltages VPASS1, VPASS2. The programming operation then continues.

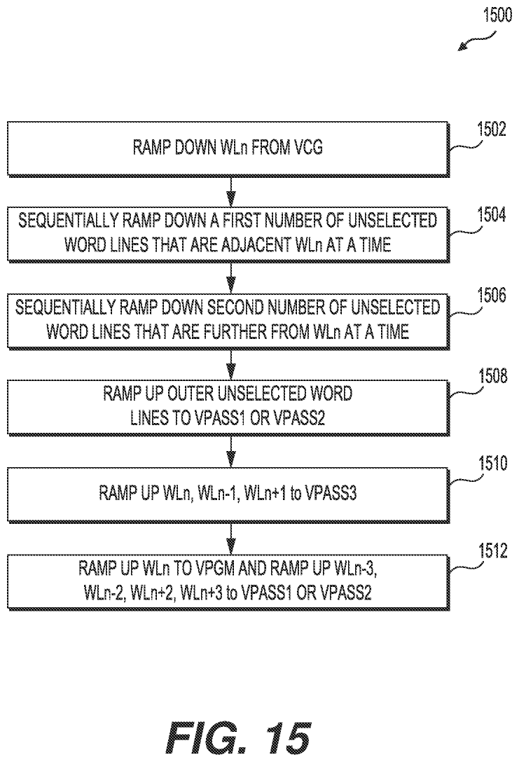

Turning now to FIG. 15, a flow chart 1500 is provided that depicts the steps of performing a word line ramp down process followed by a word line ramp up process according to another example embodiment of the subject disclosure. These steps could be performed by the controller; a processor or processing device or any other circuitry, executing instructions stored in memory; and/or other circuitry described herein that is specifically configured/programmed to execute the following steps. This embodiment is similar to the embodiment illustrated in FIG. 14 and discussed above, but the ramp down process occurs in two stages.

The following steps begin at the end of a program-verify pulse. At this time, a reference voltage VCG is being applied to a selected word line WLn and pass voltages VREAD are being applied to the unselected word lines on either side of the selected word line WLn. At step 1502, the selected word line WLn is ramped down from the reference voltage VCG to either a negative voltage-VNWL or approximately 0 V.

At step 1504, a first stage of a two-stage ramp down process begins. In the first stage, a first number of unselected word lines, which are adjacent the selected word line WLn, are sequentially ramped down together in a group from the pass voltages VREAD to approximately 0 V (or a negative voltage if the memory block is able to apply negative voltages to multiple word lines simultaneously). The first number of unselected word lines includes no more than the four closest word lines WLn−2, WLn−1, WLn+1, WLn+2 to the selected word line WLn. In a presently preferred embodiment, the first number of unselected word lines includes only the two unselected word lines WLn−1, WLn+1 that are immediately adjacent the selected word line WLn. The first stage continues for three to five steps, e.g., unselected word lines WLn−1, WLn+1 ramp down first, then unselected word lines WLn−2, WLn+2, then unselected word lines WLn−3, WLn+3, etc.

At step 1506, the second stage of the ramp down process begins. In the second stage, the remaining unselected word lines are ramped down from the pass voltages VREAD to approximately 0 V. However, in the second stage, the unselected word lines are ramped down by a second number of unselected word lines at a time with the second number of unselected word lines being greater than the first number of unselected word lines. For example, in some embodiments, during the second stage, six or more unselected word lines are ramped down at a time starting from the nearest unselected word lines that did not get ramped down in the first phase. In an embodiment where WLn−2, WLn−1, WLn+1, and WLn+2 all ramped down during the first stage, then in the second phase, WLn−5, WLn−4, WLn−3, WLn+3, WLn+4, and WLn+5 can all ramp down during a first step of the second stage. Then, in the second step of the second stage, WLn−8, WLn−7, WLn−6, WLn+6, WLn+7, and WLn+8 can all ramp down. This pattern continues until all of the unselected word lines in the memory block have ramped down to 0 V.

At step 1508, the outer unselected word lines are ramped up to their respective pass voltages VPASS1, VPASS2. The outer unselected word lines include all of the word lines that are distant from the selected word line WLn. For example, in one embodiment, the outer word lines include all of the word lines that are four or more word lines away from the selected word line WLn, i.e., WL0 through WLn−4 and WLn+4 through WLN where “N” is the last word line in the memory block.

At step 1510, the selected word line WLn and the two immediately adjacent word lines WLn−1, WLn+1 are ramped up to the pass voltage VPASS3. Finally, at step 1512, the selected word line WLn is ramped up further from VPASS3 to the programming voltage VPGM and the remaining unselected word lines WLn−3, WLn−2, WLn+2, WLn+3 are ramped up to their respective pass voltages VPASS1, VPASS2. The programming operation then continues.

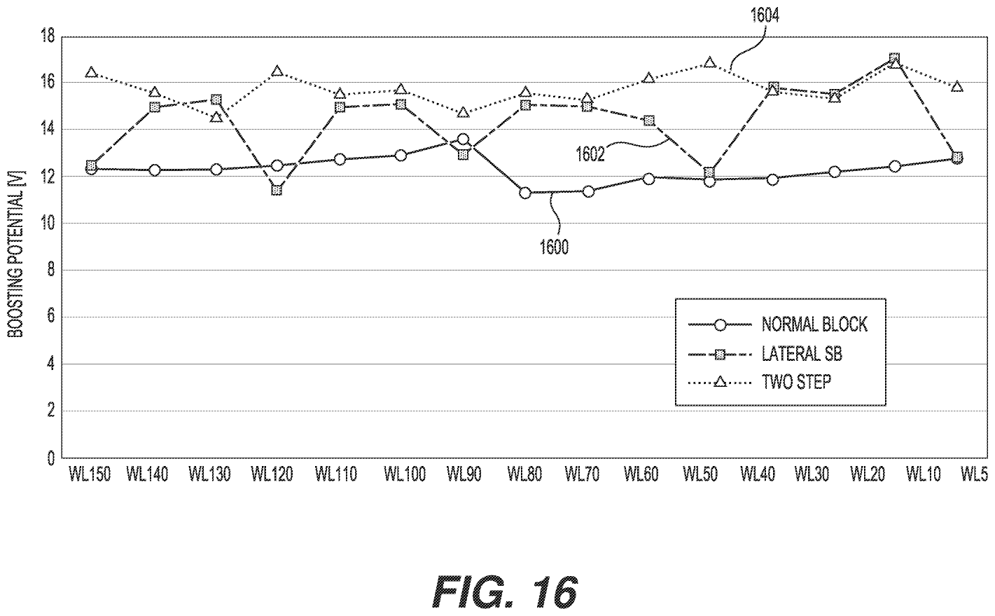

By ramping down in two stages rather than one, the boosting potential can be further improved as compared to the single stage ramp down process depicted in the embodiment of FIG. 14. For example, FIG. 16 depicts boosting potential versus word line following three ramp up processes: a conventional process where the memory block is in a normal block mode (line 1600), a single-stage ramp up process where the memory block is in a lateral sub-block mode (line 1602), and a two-stage ramp up process where the memory block is in a lateral sub-block mode (line 1604). As illustrated, in this example, the two-stage ramp up process generally offers the highest bosting potential of the three options for the substantial majority of the word lines.

Various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that includes customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it includes one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that includes the element.

The terms “a,” “an,” and “the” also refer to “one or more” unless expressly specified otherwise. By way of example, “a processor” programmed to perform various functions refers to one processor programmed to perform each and every function or more than one processor collectively programmed to perform each of the various functions. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or more,” “ones or more,” and/or “ones or mores” according to set theory, unless expressly specified otherwise.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application to thereby enable others skilled in the art to best utilize the technology in various embodiments and with various modifications as are suited to the particular use contemplated. The scope of the technology is defined by the claims appended hereto.

What is claimed is:

1. A method of performing a programming operation in a memory device, comprising the steps of:
preparing a memory block that includes an array of memory cells that are arranged in a plurality of word lines;
with the memory block operating in a lateral sub-block mode;
ramping down a selected word line being programmed from a reference voltage;
after beginning to ramp down the selected word line from the reference voltage, sequentially ramping down a plurality of unselected word lines from pass voltages from nearest the selected word line to the opposite ends of the memory block;
after the unselected word lines have been sequentially ramped down, ramping up a plurality of unselected word lines that are distant from the selected word line; and
after the unselected word lines that are distant from the selected word line have begun to ramp up, ramping up the selected word line to a programming voltage.

2. The method as set forth in claim 1, wherein the step of sequentially ramping down the plurality of unselected word lines begins with only ramping down at least two word lines that are nearest the selected word line and then only ramping down at least two next closest word lines and continues until all of the unselected word lines in the memory block have begun to ramp down from the pass voltages.

3. The method as set forth in claim 2, wherein the step of sequentially ramping down the plurality of unselected word lines includes a first stage and a second stage,
wherein during the first stage, a first number of unselected word lines simultaneously begin to ramp down,
wherein during the second stage, a second number of unselected word lines simultaneously begin to ramp down, and
wherein the second number of unselected word lines is greater than the first number of unselected word lines.

4. The method as set forth in claim 3, wherein the first number of unselected word lines includes no more than four unselected word lines.

5. The method as set forth in claim 1, wherein the step of ramping down the selected word line from the reference voltage includes ramping the selected word line down to a negative voltage.

6. The method as set forth in claim 5, wherein the step of sequentially ramping down the plurality of unselected word lines from the pass voltages includes ramping the unselected word lines down to approximately zero Volts.

7. The method as set forth in claim 5, wherein after the step of ramping up the plurality of unselected word lines that are distant from the selected word line and prior to the step of ramping up the selected word line to the programming voltage, the method further includes the step of ramping up the selected word line from the negative voltage to a positive voltage that is less than the programming voltage.

8. The method as set forth in claim 1, wherein after the step of ramping up the selected word line to the programming voltage, the method further includes the step of ramping up a plurality of remaining unselected word lines to pass voltages.

9. A memory device for performing a programming operation, comprising:
a memory block that includes an array of memory cells that are arranged in a plurality of word lines, the array being divided into at least two laterally divided sub-blocks;
control circuitry that is configured to program the memory cells of one of the sub-blocks in a plurality of program loops, during at least one of the program loops the control circuitry being configured to;
ramp down a selected word line being programmed from a reference voltage;
after beginning to ramp down the selected word line from the reference voltage, sequentially ramp down a plurality of unselected word lines from pass voltages from nearest the selected word line to the opposite ends of the memory block;
after the unselected word lines have been sequentially ramped down, ramp up a plurality of unselected word lines that are distant from the selected word line; and
after the unselected word lines that are distant from the selected word line have begun to ramp up, ramp up the selected word line to a programming voltage.

10. The memory device as set forth in claim 9, wherein when sequentially ramping down the plurality of unselected word lines, the control circuitry is configured to initially only ramp down at least two word lines that are nearest the selected word line and then only ramp down at least two next closest word lines and continue to ramp down the unselected word lines until all of the unselected word lines in the memory block have begun to ramp down from the pass voltages.

11. The memory device as set forth in claim 10, wherein the control circuitry is configured to sequentially ramp down the plurality of unselected word lines in a first stage and a second stage,
wherein during the first stage, the control circuitry simultaneously begins to ramp down a first number of unselected word lines,
wherein during the second stage, the control circuitry simultaneously begins to ramp down a second number of unselected word lines, and
wherein the second number of unselected word lines is greater than the first number of unselected word lines.

12. The memory device as set forth in claim 11, wherein the first number of unselected word lines includes no more than four unselected word lines.

13. The memory device as set forth in claim 9, wherein the control circuitry is configured to ramp down the selected word line from the reference voltage to a negative voltage.

14. The memory device as set forth in claim 13, wherein the circuitry is configured to sequentially ramp down the plurality of unselected word lines from the pass voltages to approximately zero Volts.

15. The memory device as set forth in claim 13, wherein after ramping up the plurality of unselected word lines that are distant from the selected word line and prior to ramping up the selected word line to the programming voltage, the control circuitry is further configured to ramp up the selected word line from the negative voltage to a positive voltage that is less than the programming voltage.

16. The memory device as set forth in claim 9, wherein after ramping up the selected word line to the programming voltage, the control circuitry is further configured to ramp up a plurality of remaining unselected word lines to pass voltages.

17. An apparatus for performing a programming operation in a memory device, comprising:
a memory block that includes an array of memory cells that are arranged in a plurality of word lines, the array being divided into at least two laterally divided sub-blocks;
a programming means for programming the memory cells of one of the sub-blocks in a plurality of program loops, during at least one of the program loops the programming means being configured to;
ramp down a selected word line being programmed from a reference voltage,
after beginning to ramp down the selected word line from the reference voltage, sequentially ramp down a plurality of unselected word lines from pass voltages from nearest the selected word line to the opposite ends of the memory block,
after the unselected word lines have been sequentially ramped down, ramp up a plurality of unselected word lines that are distant from the selected word line, and
after the unselected word lines that are distant from the selected word line have begun to ramp up, ramp up the selected word line to a programming voltage.

18. The apparatus as set forth in claim 17, wherein when sequentially ramping down the plurality of unselected word lines, the programming means is configured to initially only ramp down at least two word lines that are nearest the selected word line and then only ramp down at least two next closest word lines and continue to ramp down the unselected word lines until all of the unselected word lines in the memory block have begun to ramp down from the pass voltages.

19. The apparatus as set forth in claim 18, wherein the programming means is configured to sequentially ramp down the plurality of unselected word lines in a first stage and a second stage,
wherein during the first stage, the programming means simultaneously begins to ramp down a first number of unselected word lines,
wherein during the second stage, the programming means simultaneously begins to ramp down a second number of unselected word lines, and
wherein the second number of unselected word lines is greater than the first number of unselected word lines.

20. The apparatus as set forth in claim 19, wherein the first number of unselected word lines includes no more than four unselected word lines.
